(19) United States
(12) Patent Application Publication
(10) Pub. No.: US 2024/0304704 A1
(43) Pub. Date: Sep. 12, 2024

(54) INTEGRATED CIRCUIT DEVICE

(71) Applicant: Samsung Electronics Co., Ltd., Suwon-si (KR)

(72) Inventors: Subin Lee, Suwon-si (KR); Hyunjun Lim, Suwon-si (KR); Jeonghyeon Lee, Suwon-si (KR); Hakjong Lee, Suwon-si (KR); Taeho Cha, Suwon-si (KR); Seunghyeon Hong, Suwon-si (KR)

(21) Appl. No.: 18/592,697

(22) Filed: Mar. 1, 2024

(30) Foreign Application Priority Data
Mar. 8, 2023 (KR) 10-2023-0030815

(51) Int. Cl. H01L 29/66; H01L 21/762; H01L 21/8234; H01L 27/088; H01L 29/06; H01L 29/423; H01L 29/775; H01L 29/78; H01L 29/786

(52) U.S. Cl. CPC H01L 29/66545; H01L 21/76224; H01L 21/823437; H01L 21/823481; H01L 27/0886; H01L 29/0649; H01L 29/0673; H01L 29/42392; H01L 29/66439; H01L 29/66795; H01L 29/775; H01L 29/785; H01L 29/78696

(57) ABSTRACT

Provided is an integrated circuit device including a plurality of fin-type active areas each extending on a substrate in a first horizontal direction, a plurality of gate structures each extending in a second horizontal direction intersecting the plurality of fin-type active areas on the substrate and spaced apart from each other in the first horizontal direction, an interlayer insulating layer covering the periphery of the plurality of gate structures, and an inter-gate cutting layer formed of an insulating material and extending in the first horizontal direction across through the plurality of gate structures and the interlayer insulating layer. A first gate structure is separated from a second gate structure by the inter-gate cutting layer, and portions of respective side surfaces of the gate structures overlap the plurality of fin-type active areas in a vertical direction, the respective side surfaces of the gate structures extending in the first horizontal direction.

### CROSS-REFERENCE TO RELATED APPLICATION

This application is based on and claims priority under 35 U.S.C. § 119 to Korean Patent Application No. 10-2023-0030815, filed on Mar. 8, 2023, in the Korean Intellectual Property Office, the disclosure of which is incorporated by reference herein in its entirety.

### BACKGROUND

The inventive concept relates to integrated circuit (IC) devices, and more particularly, to an IC device including a field-effect transistor.

As the sizes of integrated circuit devices decrease, integration degrees of field-effect transistors on a substrate need to be increased, and accordingly, a nanosheet field-effect transistor (NSFET) including a plurality of nanosheets stacked on the same layout area has been developed. Recently, as the integration degrees of integrated circuit devices further increase and the sizes of integrated circuit devices are further reduced, the development of a new structure capable of improving performance and reliability of nanosheet field-effect transistors is needed.

### SUMMARY

The inventive concept provides an integrated circuit device capable of providing stable performance and improved reliability in a nanosheet field-effect transistor by forming an inter-gate cutting layer in a stepped structure and making respective horizontal widths of an upper portion and a lower portion of the inter-gate cutting layer different from each other.

Additional aspects will be set forth in part in the description which follows and, in part, will be apparent from the description, or may be learned by practice of the presented embodiments.

In accordance with an aspect of the disclosure, an integrated circuit device includes a plurality of fin-type active areas each extending on a substrate in a first horizontal direction; a plurality of gate structures each extending in a second horizontal direction intersecting the plurality of fin-type active areas on the substrate, the plurality of gate structures being spaced apart from each other in the first horizontal direction; an interlayer insulating layer covering a periphery of the plurality of gate structures; and an inter-gate cutting layer formed of an insulating material and extending in the first horizontal direction through the plurality of gate structures and the interlayer insulating layer, wherein a first gate structure of the plurality of gate structures is separated from a second gate structure of the plurality of gate structures by the inter-gate cutting layer, and portions of respective side surfaces of the plurality of gate structures overlap the plurality of fin-type active areas in a vertical direction, the respective side surfaces of the plurality of gate structures extending in the first horizontal direction.

In accordance with an aspect of the disclosure, an integrated circuit device includes first and second fin-type active areas each extending in a first horizontal direction on a substrate and spaced apart from each other in a second horizontal direction crossing the first horizontal direction; a gate structure extending in the second horizontal direction to intersect the first and second fin-type active areas on the substrate; an inter-gate isolation trench cutting through the gate structure in the first horizontal direction; and an inter-gate cutting layer filling the inter-gate isolation trench and having an upper portion and a lower portion, wherein a sidewall of the upper portion includes a first insulating liner and a second insulating liner, and a sidewall of the lower portion includes the second insulating liner, wherein the first insulating liner overlaps the first and second fin-type active areas in a vertical direction, and the second insulating liner does not overlap the first and second fin-type active areas in the vertical direction.

In accordance with an aspect of the disclosure, an integrated circuit device includes a plurality of fin-type active areas each extending on a substrate in a first horizontal direction; a plurality of nanosheet stacks respectively disposed over the plurality of fin-type active areas and each including at least one nanosheet; a plurality of gate structures each extending in a second horizontal direction intersecting the plurality of fin-type active areas on the substrate, spaced apart from each other in the first horizontal direction, and surrounding the plurality of nanosheet stacks; an interlayer insulating layer covering a periphery of the plurality of gate structures; an inter-gate isolation trench cutting through the plurality of gate structures in the first horizontal direction; and an inter-gate cutting layer filling the inter-gate isolation trench and having an upper portion and a lower portion, wherein a sidewall of the upper portion includes a first insulating liner and a second insulating liner, and a sidewall of the lower portion includes the second insulating liner, wherein the first insulating liner overlaps the plurality of nanosheet stacks in a vertical direction, and the second insulating liner does not overlap the plurality of nanosheet stacks in the vertical direction.

### BRIEF DESCRIPTION OF THE DRAWINGS

Example embodiments of the inventive concept will be more clearly understood from the following detailed description taken in conjunction with the accompanying drawings in which:

FIG. 1 is a schematic perspective view of an integrated circuit device according to an embodiment;

FIG. 2 is a planar layout diagram of an integrated circuit device according to an embodiment;

FIG. 3A is a cross-sectional view taken along line A-A′ of FIG. 2;

FIG. 3B is a cross-sectional view taken along line B-B′ of FIG. 2;

FIG. 3C is a cross-sectional view taken along line C-C′ of FIG. 2;

FIGS. 4 and 5 are cross-sectional views of integrated circuit devices according to embodiments;

FIG. 6 is a flowchart of a method of manufacturing an integrated circuit device, according to an embodiment;

FIGS. 7A through 13C are cross-sectional views illustrating a method of manufacturing an integrated circuit device, according to an embodiment;

FIG. 14 is a schematic perspective view of an integrated circuit device according to an embodiment;

FIGS. 15 and 16 are cross-sectional views corresponding to active patterns of the integrated circuit device of FIG. 14; and

FIG. 17 is a schematic diagram of a structure of a system including an integrated circuit device according to an embodiment.

### DETAILED DESCRIPTION OF THE EMBODIMENTS

Embodiments of the inventive concept will now be described more fully with reference to the accompanying drawings.

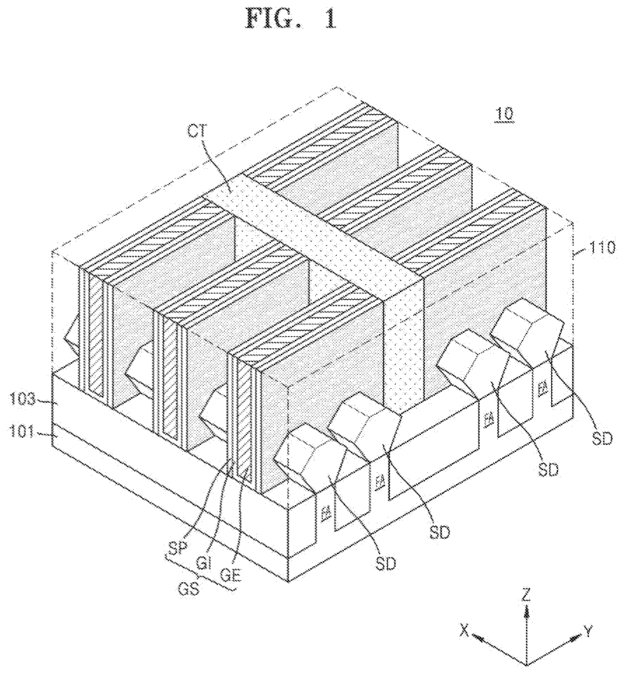

FIG. 1 is a schematic perspective view of an integrated circuit device according to an embodiment.

FIG. 1 illustrates an integrated circuit device 10 including a field-effect transistor including a fin-type active area FA.

In detail, the integrated circuit device 10 may include a plurality of fin-type active areas FA each extending in a first horizontal direction (e.g., an X direction) on a substrate 101, and a plurality of gate structures GS each extending in a second horizontal direction (e.g., a Y direction) intersecting the plurality of fin-type active areas FA and spaced apart from one another in the first horizontal direction (X direction). According to some embodiments, the plurality of gate structures GS may include a gate electrode GE, a gate dielectric layer GI, and a gate spacer SP.

For example, the plurality of fin-type active areas FA may protrude from a top surface of the substrate 101. It should be noted that in some embodiments, the fin-type active areas FA may be part of the substrate 101, and in this manner, protruding from the substrate refers to protruding past a top surface of the substrate (e.g., wherein the substrate itself has protrusions that extend beyond a main surface thereof).

The integrated circuit device 10 may also include source/drain regions SD formed in portions of the plurality of fin-type active areas FA not covered by the plurality of gate structures GS, an interlayer insulating layer 110 covering the periphery of the plurality of gate structures GS, and an inter-gate cutting layer CT extending across through the plurality of gate structures GS and the interlayer insulating layer 110 in the first horizontal direction (X direction).

As a feature size of the integrated circuit device 10 decreases, the integrated circuit device 10 is gradually being ultra-highly integrated and miniaturized. Accordingly, to increase an effect of using the side surfaces of the fin-type active areas FA constituting a fin-type field-effect transistor (FinFET) or a nanosheet field-effect transistor (NSFET) as a channel, heights of the gate structures GS are gradually increasing. As such, as the heights of the gate structures GS increase, process difficulties are gradually increasing when the gate structures GS necessary for the integrated circuit device 10 are formed using a replacement metal gate (RMG) process and are cut by the inter-gate cutting layer CT.

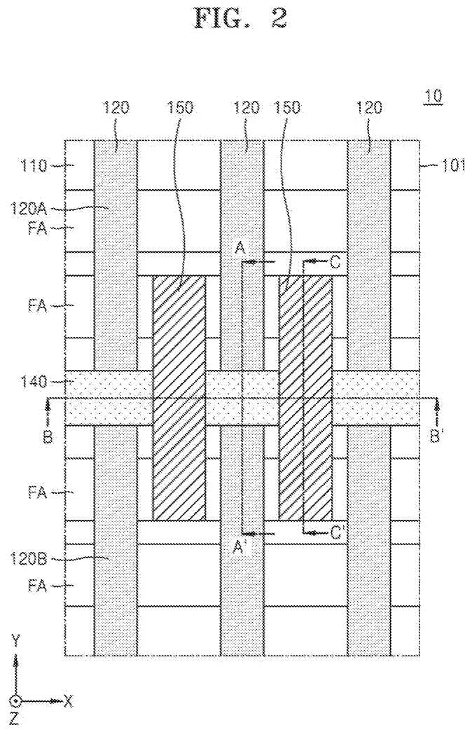

In the integrated circuit device 10 according to the inventive concept, after a process of replacing a dummy gate pattern with the gate electrode GE including a metal material by using the RMG process, the inter-gate cutting layer CT is formed in a stepped structure, and thus the gate electrode GE may be patterned and separated into a pair of gate electrodes GE facing each other and spaced apart from each other in the second horizontal direction (Y direction). For example, the formation of the inter-gate cutting layer CT may divide a gate electrode GE into a pair of gate electrodes GE. For example, a first gate structure 120A may be separated from a second gate structure 120B by the inter-gate cutting layer CT (see, e.g., FIG. 2).

Accordingly, the integrated circuit device 10 according to the inventive concept may provide stable performance and improved reliability in a fin-type field-effect transistor (FinFET) or a nanosheet field-effect transistor (NSFET) by forming the inter-gate cutting layer CT in a stepped structure and making respective horizontal widths of an upper portion and a lower portion of the inter-gate cutting layer CT different from each other.

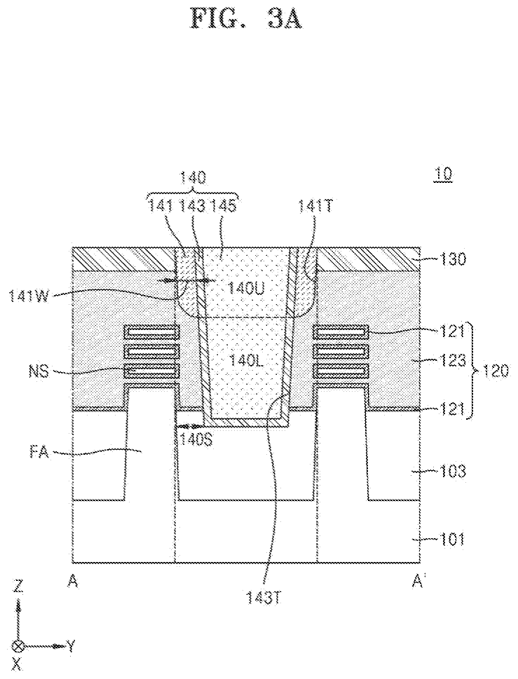

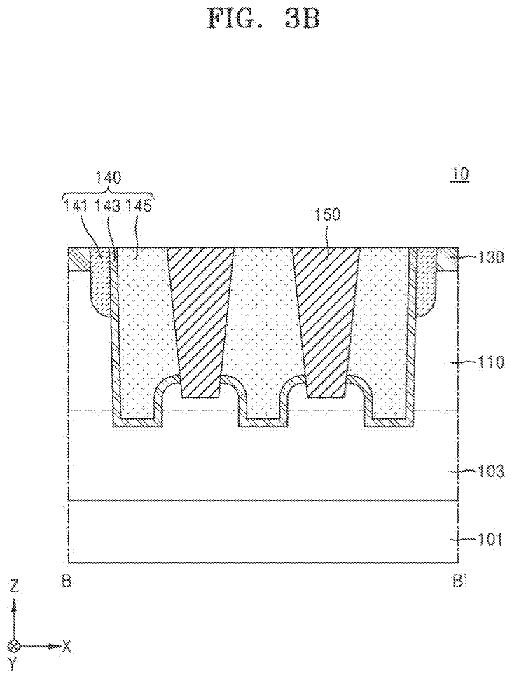

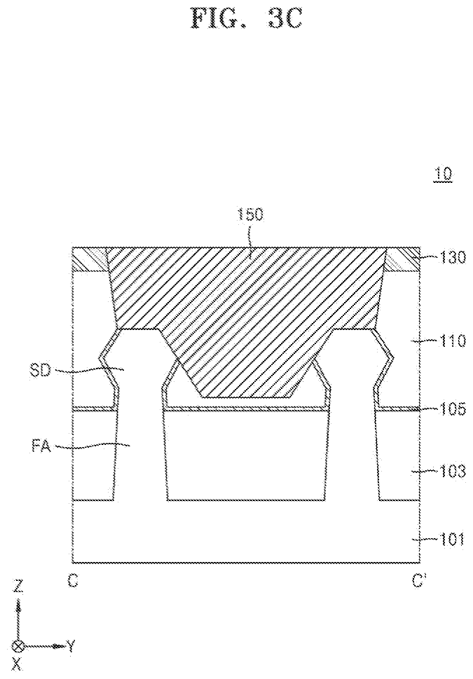

FIG. 2 is a planar layout diagram of an integrated circuit device according to an embodiment, FIG. 3A is a cross-sectional view taken along line A-A′ of FIG. 2, FIG. 3B is a cross-sectional view taken along line B-B′ of FIG. 2, and FIG. 3C is a cross-sectional view taken along line C-C′ of FIG. 2.

FIG. 2 and FIGS. 3A through 3C illustrate an integrated circuit device 10 including a fin-type active area FA, a nanosheet stack NS, an interlayer insulating layer 110, a gate structure 120, an upper insulating layer 130, an inter-gate cutting layer 140, and a contact structure 150 disposed on a substrate 101.

The substrate 101 may be a wafer including silicon (Si). According to some embodiments, the substrate 101 may be a wafer including a semiconductor element, such as, germanium (Ge), or a compound semiconductor, such as, Si carbide (SiC), gallium arsenide (GaAs), indium arsenide (InAs), or indium phosphide (InP). The substrate 101 may have a silicon-on-insulator (SOI) structure. The substrate 101 may include a conductive region, for example, an impurity-doped well or an impurity-doped structure.

The interlayer insulating layer 110 may be disposed on a source/drain region SD and an isolation layer 103. The interlayer insulating layer 110 may be formed to contact outer walls of a plurality of gate structures 120. The interlayer insulating layer 110 may include, as an insulating material, for example, at least one of silicon oxide, silicon nitride, silicon oxynitride, and a low-k dielectric material.

On and across the plurality of fin-type active areas FA, the plurality of gate structures 120 may each extend in the second horizontal direction (Y direction). In regions where the plurality of fin-type active areas FA intersect the plurality of gate structures 120, a plurality of nanosheet stacks NS may be arranged over the plurality of fin-type active areas FA, respectively. The plurality of nanosheet stacks NS may be disposed spaced apart from the plurality of fin-type active areas FA in a vertical direction (e.g., a Z direction). The term nanosheet used herein refers to a conductive structure having a cross section substantially perpendicular to a direction in which current flows. It should be understood that the nanosheet may include nanowires.

The plurality of gate structures 120 may be spaced apart from each other in the first horizontal direction (X direction) on the substrate 101 and each may extend in a second horizontal direction (Y direction). The plurality of gate structures 120 may be disposed on the fin-type active areas FA and the isolation layer 103. Each of the plurality of gate structures 120 may include a gate dielectric layer 121, a gate electrode 123, and the gate spacer SP of FIG. 1.

The gate dielectric layer 121 may be disposed between the gate electrode 123 and a fin-type active region FA. The gate dielectric layer 121 may also be disposed between the gate electrode 123 and a nanosheet stack NS (see, e.g., FIG. 3A). The gate dielectric layer 121 may also be disposed between the gate electrode 123 and the interlayer insulating layer 110. According to some embodiments, the gate dielectric layer 121 may extend in the second horizontal direction (Y direction) along the profile of the fin-type active area FA protruding above the isolation layer 103. The gate dielectric layer 121 may be disposed to surround the nanosheet stack NS.

According to some embodiments, the gate dielectric layer 121 and the gate electrode 123 may be formed through an RMG process or a gate last process. The gate dielectric layer 121 may include a high-k dielectric material having a higher dielectric constant than that of silicon oxide. For example, the gate dielectric layer 121 may include HfO₂, ZrO₂, LaO, Al₂O₃, Ta₂O₅, etc.

The gate electrode 123 may have a single layered structure, or a multi-layered structure in which at least two layers are stacked. According to some embodiments, the gate electrode 123 may include a work function control layer and a center electrode layer. The work function control layer may serve to control a work function, and the center electrode layer may serve to fill a space formed by the work function control layer. The work function control layer may include, for example, at least one of TIN, WN, TiAl, TiAlN, TaN, TiC, TaC, TaCN, TaSiN, and combinations thereof. The center electrode layer may include, for example, at least one of W, Al, Co, Ti, Ta, poly-Si, SiGe, and a metal alloy.

The source/drain regions SD may be disposed on both sides of each of the plurality of gate structures 120, respectively. The source/drain regions SD may be disposed in the fin-type active areas FA. In other words, the source/drain regions SD may be formed in partially-etched portions of the fin-type active areas FA. According to some embodiments, the source/drain regions SD may be raised source/drain regions. Accordingly, upper ends of the source/drain regions SD may be higher than those of the fin-type active areas FA.

According to some embodiments, when the integrated circuit device 10 is a pMOS transistor, the source/drain regions SD may include a compressive strain material. The compressive strain material may be a material having a greater lattice constant than silicon (Si), and may be, for example, silicon germanium (SiGe). The compressive strain material may improve carrier mobility of a channel region by applying compressive stress to the fin-type active areas FA under the plurality of gate structures 120. According to other embodiments, when the integrated circuit device 10 is an nMOS transistor, the source/drain regions SD may include the same material as the substrate 101 or a tensile strain material. The tensile strain material may be a material having a smaller lattice constant than silicon (Si), and may be, for example, silicon carbide (SIC). The tensile strain material may improve carrier mobility of the channel region by applying tensile stress to the fin-type active areas FA under the plurality of gate structures 120.

An isolation insulating layer 105 may cover the source/drain regions SD and the isolation layer 103. The interlayer insulating layer 110 may be disposed on the isolation insulating layer 105. According to some embodiments, the isolation insulating layer 105 may be formed of silicon nitride, SiCN, SiBN, SION, SiOCN, SiBCN, or a combination thereof. However, the inventive concept is not limited thereto.

An upper insulating layer 130 may be disposed on an upper surface of the interlayer insulating layer 110 and upper surfaces of the plurality of gate structures 120. According to some embodiments, the upper insulating layer 130 may serve as a hard mask layer. The upper insulating layer 130 may include, as an insulating material, at least one of, for example, a spin on hardmask (SOH), silicon oxide, silicon nitride, and silicon oxynitride.

The inter-gate cutting layer 140 may extend in the first horizontal direction (X direction) to intersect the plurality of gate structures 120. A pair of gate structures 120 disposed adjacent to each other in the second horizontal direction (Y direction) with the inter-gate cutting layer 140 interposed therebetween may be spaced apart from each other without being connected to each other. Gate structures 120 arranged in a line in the second horizontal direction (Y direction) among the plurality of gate structures 120 may be spaced apart from each other by the inter-gate cutting layer 140. A length of at least one gate structure 120 among the plurality of gate structures 120 may be limited by the inter-gate cutting layer 140.

In the integrated circuit device 10 according to the present embodiment, the plurality of gate structures 120 may be cut by the inter-gate cutting layer 140, and a portion of a cut surface of each gate structure 120 in the second horizontal direction (Y direction) may be positioned to overlap the fin-type active area FA and the nanosheet stack NS in the vertical direction (Z direction, see, e.g., FIG. 3A). For example, a portion of a cut surface (e.g., a side surface that extends in the first direction) of a gate structure 120 may be positioned to overlap, in the vertical direction, first and second fin-type active areas FA adjacent to each other as shown, e.g. in FIG. 3A.

This structure may be established through the stepped inter-gate cutting layer 140 in which a width of the inter-gate cutting layer 140 in the second horizontal direction (Y direction) has a step in the vertical direction (Z direction) from the upper surface of the substrate 101. With reference to FIG. 3A, an upper portion of the inter-gate cutting layer 140 based on the step is referred to as an inter-gate cutting layer upper portion 140U, and a lower portion of the inter-gate cutting layer 140 based on the step is referred to as an inter-gate cutting layer lower portion 140L.

The inter-gate cutting layer 140 may be configured such that a first insulating liner 141 is disposed on a sidewall of a first trench 141T in the inter-gate cutting layer upper portion 140U and the first insulating liner 141 is not disposed on a sidewall of a second trench 143T in the inter-gate cutting layer lower portion 140L. The inter-gate cutting layer 140 may include the inter-gate cutting layer upper portion 140U, the inter-gate cutting layer lower portion 140L, a second insulating liner 143 extending along outer surfaces of the inter-gate cutting layer lower portion 140L to a lower surface of the inter-gate cutting layer 140, and an insulating pattern 145 filling a space partitioned by (e.g., defined by or formed by) the second insulating liner 143. As will be described later, this may be a structural feature resulting from a manufacturing process of the inter-gate cutting layer 140.

Each of the first insulating liner 141, the second insulating liner 143, and the insulating pattern 145 constituting the inter-gate cutting layer 140 may include, for example, one of silicon nitride (SiN), silicon carbon nitride (SiCN), silicon oxide (SiO), silicon oxynitride (SiON), silicon carbide (SiC), silicon oxycarbide (SiOC), and silicon oxycarbonitride (SiOCN), but the inventive concept is not limited thereto.

According to some embodiments, the first insulating liner 141 and the second insulating liner 143 may include substantially the same materials. For example, each of the first insulating liner 141 and the second insulating liner 143 may include silicon nitride (SiN). The insulating pattern 145 may include, but is not limited to, silicon oxide (SiO).

According to other embodiments, the first insulating liner 141 and the second insulating liner 143 may include different materials. For example, the first insulating liner 141 may include silicon nitride (SiN), and the second insulating liner may include silicon oxynitride (SiON). The insulating pattern 145 may include, but is not limited to, silicon oxide (SiO).

In the integrated circuit device 10 according to the present embodiment, an outer wall of the inter-gate cutting layer upper portion 140U in the second horizontal direction (Y direction) may be disposed to overlap the upper surface of the fin-type active area FA and the upper surface of the nanosheet stack NS in the vertical direction (Z direction), and an outer wall of the inter-gate cutting layer lower portion 140L in the second horizontal direction (Y direction) may be disposed to be spaced apart from the outer wall of the fin-type active area FA in the second horizontal direction (Y direction). In the second horizontal direction (Y direction), a maximum width of the inter-gate cutting layer upper portion 140U may be equal to or greater than a separation distance between the plurality of fin-type active areas FA adjacent to each other. For example, a maximum width of the inter-gate cutting layer upper portion 140U may be equal to or greater than a maximum separation distance between the plurality of fin-type active areas FA adjacent to each other. A separation distance 140S between a side surface of a fin-type active area FA and a side surface of the inter-gate cutting layer lower portion 140L in the second horizontal direction (Y direction) may be greater than a first horizontal width 141W of the first insulating liner 141 in the second horizontal direction (Y direction).

The contact structure 150 may pass through the interlayer insulating layer 110 and the isolation insulating layer 105 in the vertical direction (Z direction) and contact the plurality of source/drain regions SD. In other words, the contact structure 150 may be a source/drain contact in contact with the source/drain regions SD. The contact structure 150 may include a conductive barrier layer and a metal plug. The conductive barrier layer may be formed of Ti, Ta, TiN, TaN, or a combination thereof, but the inventive concept is not limited thereto. The metal plug may be formed of W, Co, Cu, Ru, Mn, or a combination thereof, but the inventive concept is not limited thereto.

As the size of the integrated circuit device 10 decreases, integration degrees of a field-effect transistor on a substrate need to be increased, and accordingly, a nanosheet field-effect transistor (NSFET) including a plurality of nanosheet stacks NS stacked on the same layout area has been developed. As the integration degrees of the integrated circuit device 10 further increases and the size of the integrated circuit device 10 is further reduced, the development of a new structure capable of improving performance and reliability of the nanosheet field-effect transistor is needed.

In general, as a horizontal separation distance between the gate structure 120 and the fin-type active area FA decreases, a capacitance between the gate electrode 123 and the source/drain regions SD and a capacitance between the gate electrode 123 and the contact structure 150 advantageously decrease. However, for this improvement in electrical performance, when the inter-gate cutting layer 140 is formed in a structure in which the gate structure 120 and the fin-type active area FA are in close proximity, the integrated circuit device may be vulnerable to structural defects occurring in the fin-type active area FA. In addition, when a minimum horizontal separation distance between the gate structure 120 and the fin-type active area FA is not maintained, a shift in a threshold voltage Vth may occur, resulting in electrical performance deterioration.

Accordingly, to address these problems, the integrated circuit device 10 according to the inventive concept may provide stable performance and improved reliability in a nanosheet field effect transistor by forming the inter-gate cutting layer CT in a stepped structure and making respective horizontal widths of the inter-gate cutting layer upper portion 140U and the inter-gate cutting layer lower portion 140L different from each other.

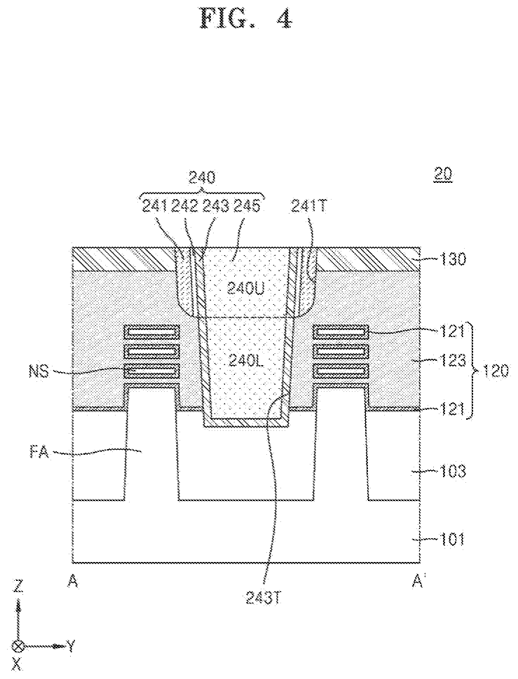

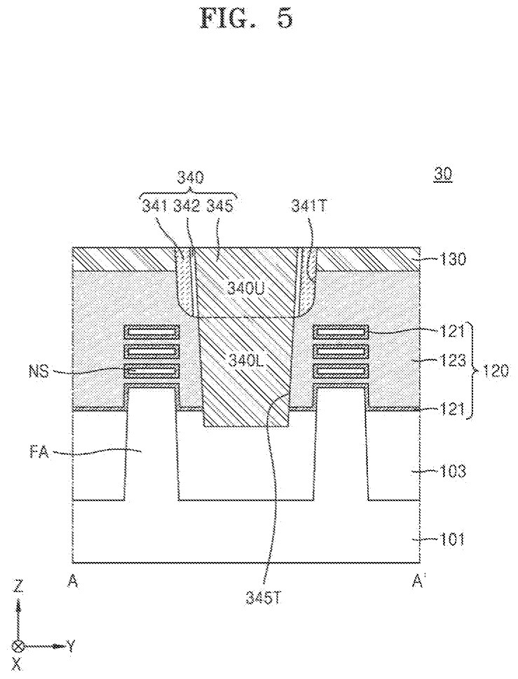

FIGS. 4 and 5 are cross-sectional views of integrated circuit devices according to embodiments.

Most of the components constituting integrated circuit devices 20 (see FIG. 4) and 30 (see FIG. 5) to be described below and materials used to form the components are substantially the same as or similar to those described above with reference to FIG. 2 and FIGS. 3A through 3C. Accordingly, differences between the integrated circuit devices 20 and 30 and the above-described integrated circuit device 10 will be mainly described for convenience of explanation.

FIG. 4 illustrates the integrated circuit device 20 including a fin-type active area FA, a nanosheet stack NS, a gate structure 120, an upper insulating layer 130, and an inter-gate cutting layer 240 disposed on a substrate 101.

The inter-gate cutting layer 240 of the integrated circuit device 20 according to the present embodiment may be configured such that a first insulating liner 241 is disposed on an outermost portion of an inter-gate cutting layer upper portion 240U and the first insulating liner 241 is not disposed on the outermost portion of an inter-gate cutting layer lower portion 240L. The inter-gate cutting layer 240 may include the inter-gate cutting layer upper portion 240U, the inter-gate cutting layer lower portion 240L, a second insulating liner 243 extending to a lower surface of the inter-gate cutting layer 240, and an insulating pattern 245 filling a space partitioned by (e.g., defined by or formed by) the second insulating liner 243. A natural oxide layer 242 may be formed between the first insulating liner 241 and the second insulating liner 243. As will be described later, the natural oxide layer 242 may be a structural feature resulting from a manufacturing process of the inter-gate cutting layer 240.

According to some embodiments, the first insulating liner 241 and the second insulating liner 243 may include substantially the same materials. For example, each of the first insulating liner 241 and the second insulating liner 243 may include silicon nitride (SiN). The insulating pattern 245 may include silicon oxide (SiO). As such, a boundary surface between the first insulating liner 241 and the second insulating liner 243 made of substantially the same materials may be specified by (e.g., defined by or formed by) the natural oxide layer 242.

FIG. 5 illustrates the integrated circuit device 30 including a fin-type active area FA, a nanosheet stack NS, a gate structure 120, an upper insulating layer 130, and an inter-gate cutting layer 340 disposed on a substrate 101.

The inter-gate cutting layer 340 of the integrated circuit device 30 according to the present embodiment may be configured such that an insulating liner 341 is disposed on an outermost portion of an inter-gate cutting layer upper portion 340U and the insulating liner 341 is not disposed on the outermost portion of an inter-gate cutting layer lower portion 340L. The inter-gate cutting layer 340 may include an insulating pattern 345 filling both the inter-gate cutting layer upper portion 340U and the inter-gate cutting layer lower portion 340L. Unlike the embodiment shown in FIG. 4, a second insulating liner may not be formed in the inter-gate cutting layer 340 of the embodiment shown in FIG. 5. A natural oxide layer 342 may be formed between the insulating liner 341 and the insulating pattern 345. As will be described later, the natural oxide layer 342 may be a structural feature resulting from a manufacturing process of the inter-gate cutting layer 340.

According to some embodiments, the insulating liner 341 and the insulating pattern 345 may include substantially the same materials. For example, each of the insulating liner 341 and the insulating pattern 345 may include silicon nitride (SiN). As such, a boundary surface between the insulating liner 341 and the insulating pattern 345 made of substantially the same materials may be specified by (e.g., defined by or formed by) the natural oxide layer 342.

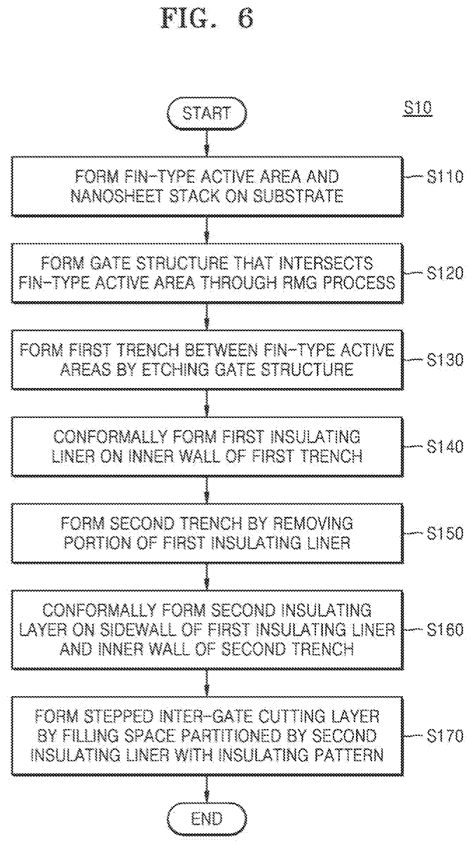

FIG. 6 is a flowchart of a method S10 of manufacturing an integrated circuit device, according to an embodiment.

Referring to FIG. 6, the method S10 of manufacturing an integrated circuit device may include first through seventh operations S110 through S170.

A specific process order may be performed differently from the described order according to embodiments. For example, two consecutively described processes may be performed substantially at the same time or performed in an order opposite to the described order.

The method S10 of manufacturing an integrated circuit device, according to the inventive concept may include first operation S110 of forming a fin-type active area and a nanosheet stack on a substrate, second operation S120 of forming a gate structure that intersects the fin-type active area through an RMG process, third operation S130 of forming a first trench between fin-type active areas by etching a gate structure, fourth operation S140 of conformally forming a first insulating liner on an inner wall of the first trench, fifth operation S150 of forming a second trench by removing a portion of the first insulating liner, sixth operation S160 of conformally forming a second insulating layer on a sidewall of the first insulating liner and an inner wall of the second trench, and seventh operation S170 of forming a stepped inter-gate cutting layer by filling a space partitioned by (e.g., defined by or formed by) the second insulating liner with an insulating pattern.

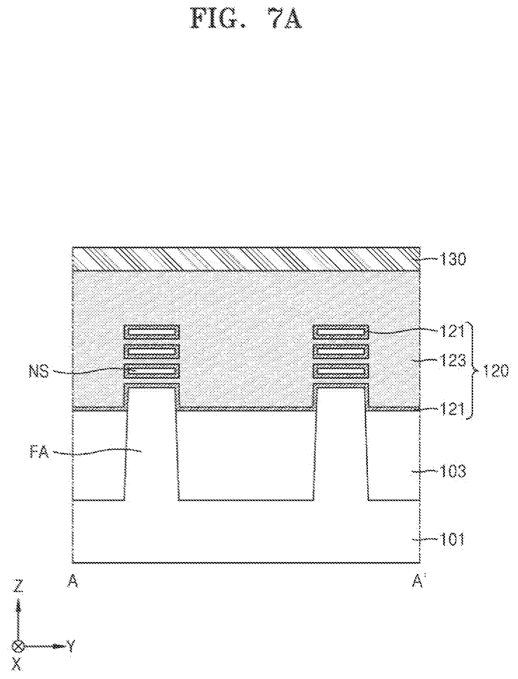

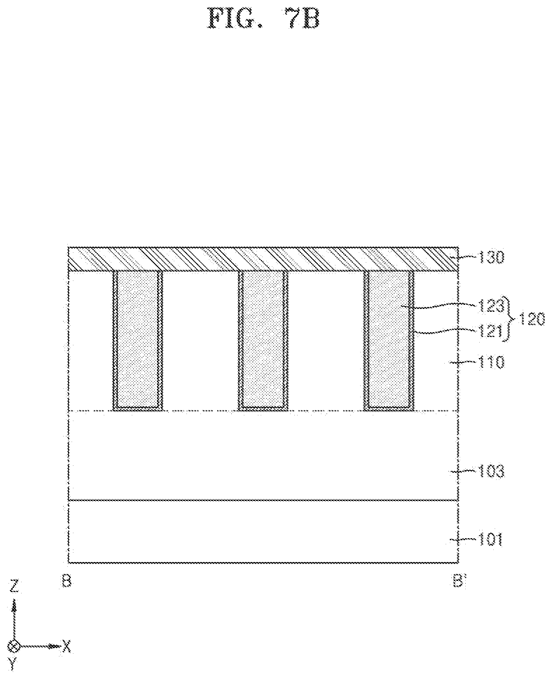

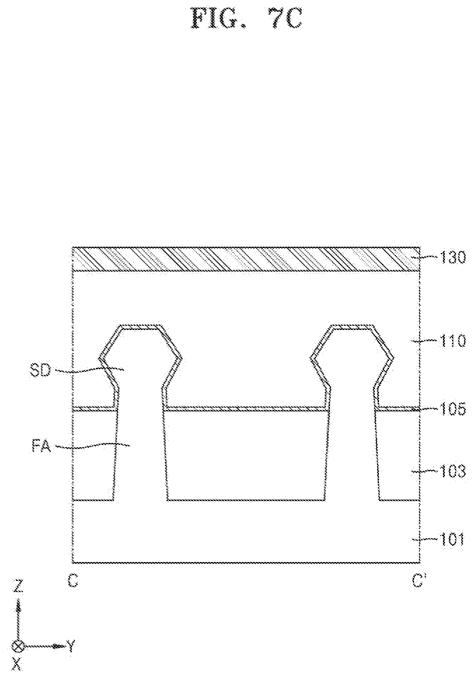

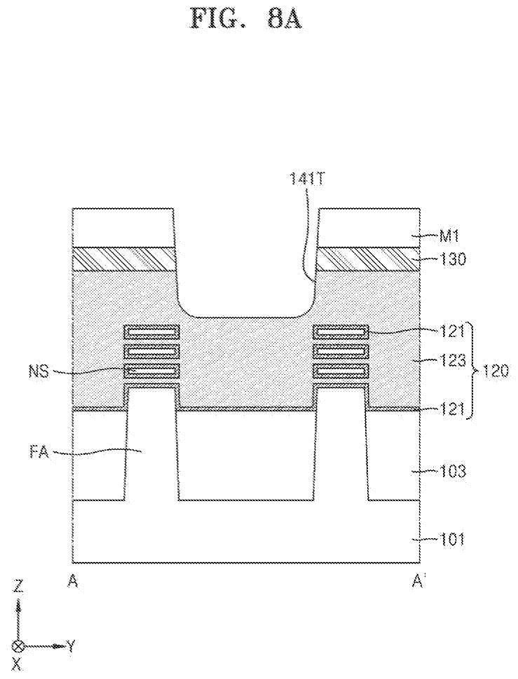

The respective technical characteristics of the first through seventh operations S110 through S170 will be described in detail with reference to FIGS. 7A through 13C.

FIGS. 7A through 13C are cross-sectional views illustrating a method of manufacturing an integrated circuit device, according to an embodiment. FIGS. 7A through 13A are cross-sectional views taken along line A-A′ of FIG. 2. FIGS. 7B through 13B are cross-sectional views taken along line B-B′ of FIG. 2. FIGS. 7C through 13C are cross-sectional views taken along line C-C′ of FIG. 2.

Referring to FIGS. 7A through 7C, a fin-type active area FA and a nanosheet stack NS each protruding from the upper surface of the substrate 101 in the vertical direction (Z direction) and extending in the first horizontal direction (X direction) may be formed by etching a partial region of the substrate 101.

After an insulating layer covering the fin-type active region FA is formed on the substrate 101, the isolation layer 103 may be formed by etching the insulating layer. At this time, the fin-type active region FA may be formed to protrude from the upper surface of the isolation layer 103 and be exposed.

A plurality of gate structures 120 including a gate dielectric layer 121 and a gate electrode 123 may be sequentially formed on the fin-type active area FA and the nanosheet stack NS of the substrate 101. According to some embodiments, the gate dielectric layer 121 may include an insulating material such as silicon oxide, and the gate electrode 123 may include a conductive material such as metal.

Next, source/drain regions SD may be formed on the fin-type active region FA exposed from both sides of each of the plurality of gate structures 120 by an epitaxial growth process. An isolation insulating layer 105 may be formed to cover the source/drain regions SD and the isolation layer 103.

The interlayer insulating layer 110 may be formed to cover both sides (e.g., sides that are parallel to a Y-Z plane) of the gate dielectric layer 121. The interlayer insulating layer 110 may include an insulating material, such as Si oxide. An upper insulating layer 130 may be formed on the upper surface of the interlayer insulating layer 110 and the respective upper surfaces of the plurality of gate structures 120.

According to some embodiments, the gate dielectric layer 121 and the gate electrode 123 may be formed through a generally known RMG process or a generally known gate last process.

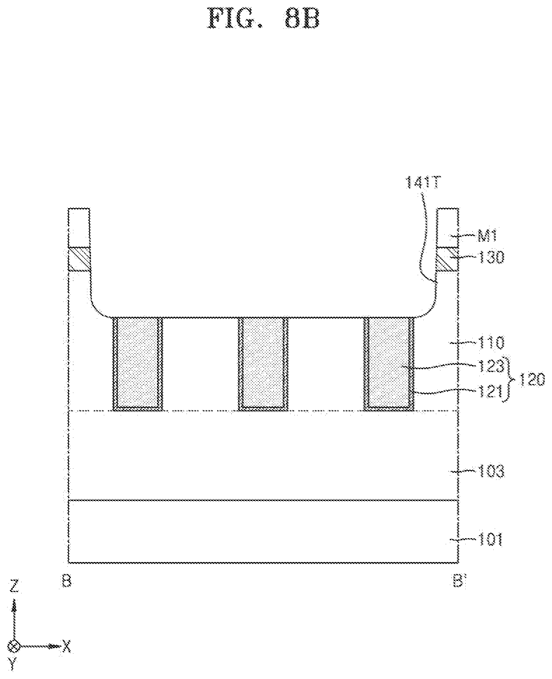

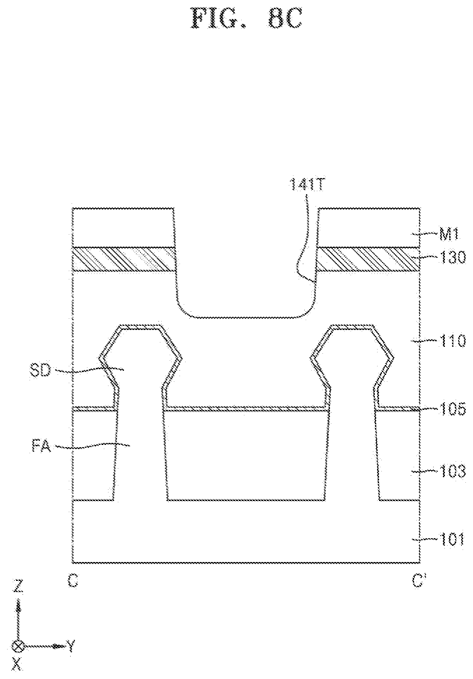

Referring to FIGS. 8A through 8C, a first photomask pattern M1 may be formed on the upper insulating layer 130.

To form the first photomask pattern M1, a photoresist (not shown) may be formed, and a photo process and a development process may be performed.

Next, an etching process of forming a first trench 141T by etching the interlayer insulating layer 110, the plurality of gate structures 120, and the upper insulating layer 130 by using the first photomask pattern M1 as an etch mask may be performed. The etching process may be, for example, a dry etching process.

The first trench 141T may be formed between a plurality of fin-type active areas FA adjacent to each other. An outer wall of the first trench 141T may be formed to overlap an upper surface of the fin-type active area FA and an upper surface of the nanosheet stack NS in the vertical direction (Z direction). A vertical level of a lowermost surface of the first trench 141T may be higher than that of an uppermost surface of the nanosheet stack NS. The longer dimension of the first trench 141T may be in the X direction (e.g., in the direction of extension of the fin-type active areas FA) and the shorter dimension of the first trench 141T may be in the Y direction (e.g., in the direction of extension of the plurality of gate structures 120).

After the etching process, the first photomask pattern M1 may be removed. The first photomask pattern M1 may be removed through an ashing and stripping process.

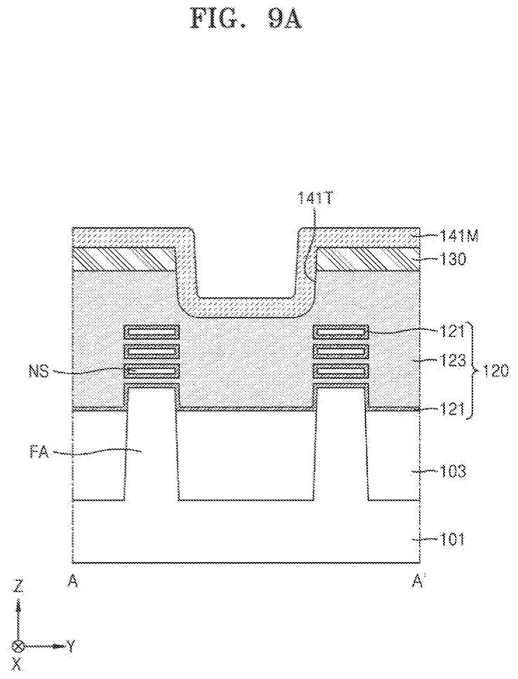

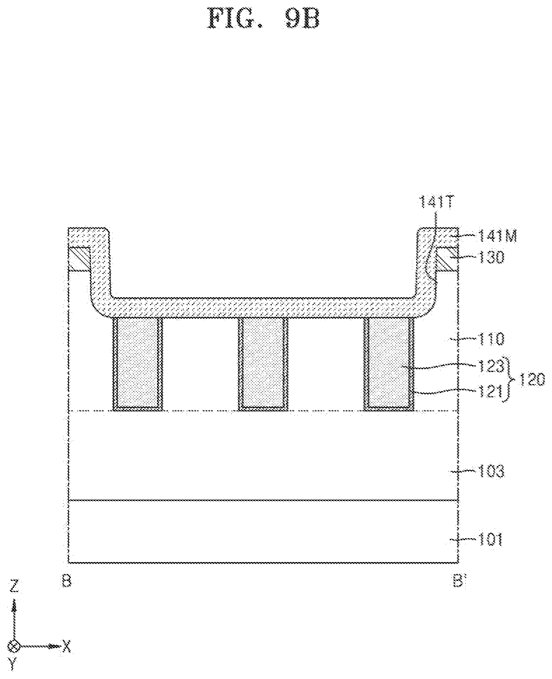

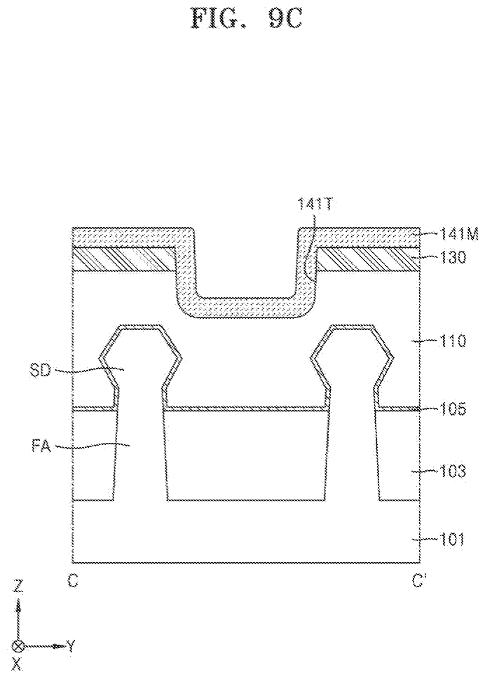

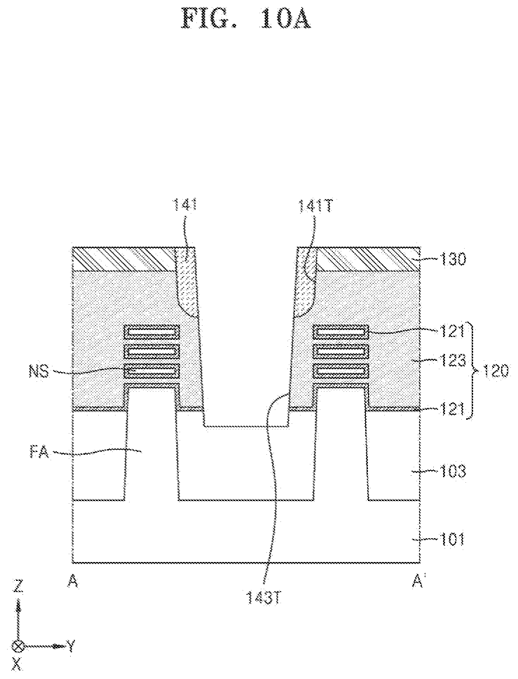

Referring to FIGS. 9A through 9C, a first insulating liner material layer 141M may be formed that is conformally disposed on the inner wall of the first trench 141T and continues along the upper surface of the upper insulating layer 130.

The first insulating liner material layer 141M may be formed of an insulating material. The first insulating liner material layer 141M may be formed of, for example, silicon nitride (SiN), silicon oxide (SiO), or silicon oxynitride (SiON), but the inventive concept is not limited thereto. According to some embodiments, the first insulating liner material layer 141M may be formed by a chemical vapor deposition process, a physical vapor deposition process, or an atomic layer deposition process, but the inventive concept is not limited thereto.

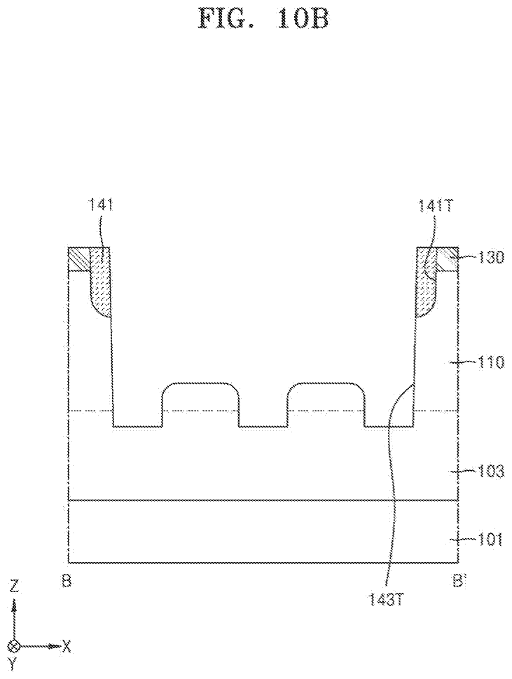

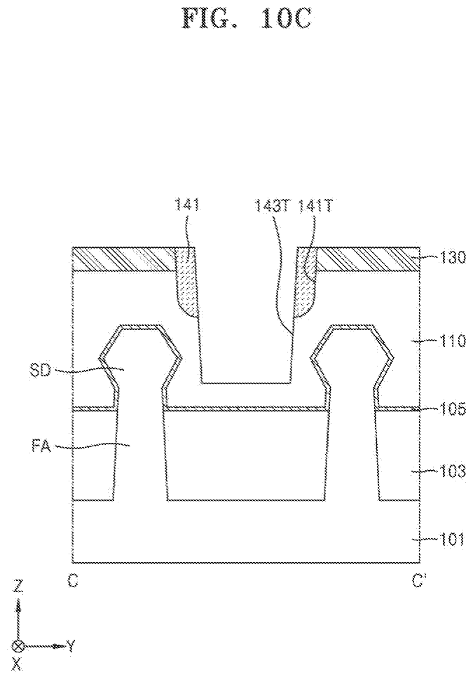

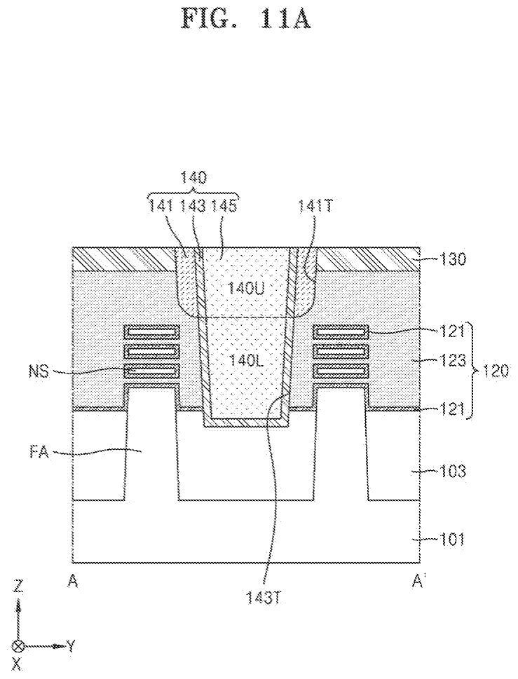

Referring to FIGS. 10A through 10C, a second trench 143T may be formed by removing portions of the first insulating liner material layer 141M, the interlayer insulating layer 110, and the gate structure 120 by using a dry etching process.

Accordingly, most of the first insulating liner material layer 141M may be removed, and the first insulating liner 141 may be formed only on the inner sidewall of the first trench 141T. Due to the dry etching process, a second trench 143T may also be formed between the plurality of fin-type active areas FA adjacent to each other. Because a horizontal width of the first trench 141T is greater than that of the second trench 143T, a step may be formed on a boundary surface between the first trench 141T and the second trench 143T.

According to some embodiments, after the dry etching process for forming the second trench 143T, a natural oxide layer may be formed on an externally exposed surface of the first insulating liner 141. Although not bound by a particular theory, surface defects may occur on the surface of the first insulating liner 141 due to the dry etching process. To heal these surface defects, a thin natural oxide layer may be formed on the surface of the first insulating liner 141.

In other words, existence of such a natural oxide layer may be due to a manufacturing process in which the first insulating liner material layer 141M is previously formed in the first trench 141T and the second trench 143T is later formed.

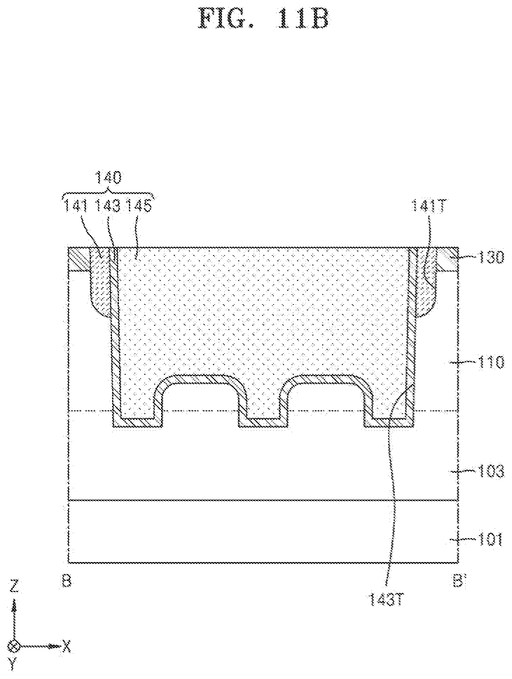

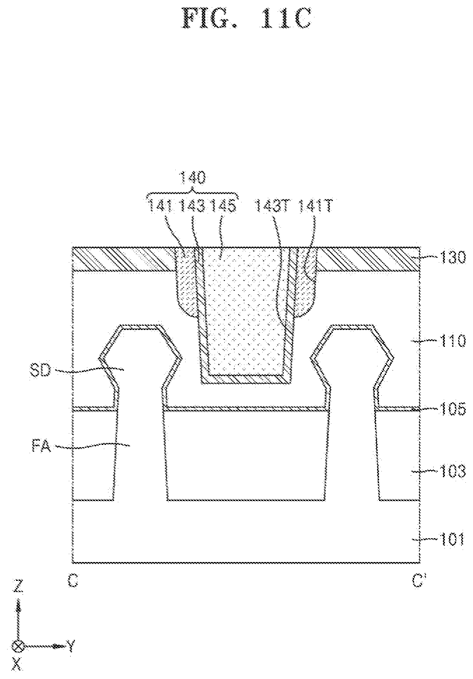

Referring to FIGS. 11A through 11C, the second insulating liner 143 may be conformally formed on the sidewalls of the first insulating liner 141 and the inner sidewalls of the second trench 143T.

The second insulating liner 143 may be formed by, for example, a chemical vapor deposition process or an atomic layer deposition process. However, the inventive concept is not limited to these processes. A thickness of the second insulating liner 143 is not particularly limited. For example, the thickness of the second insulating liner 143 may be less than that of the first insulating liner 141.

Next, an insulating pattern 145 filling the space partitioned by (e.g., defined by or formed by) the second insulating liner 143 may be formed. The insulating pattern 145 may be formed of an insulating material. According to embodiments, the insulating pattern 145 may be formed of a different material from that of the first insulating liner 141 and the second insulating liner 143. The insulating pattern 145 may be formed of, for example, silicon oxide (SiO), but embodiments are not limited thereto.

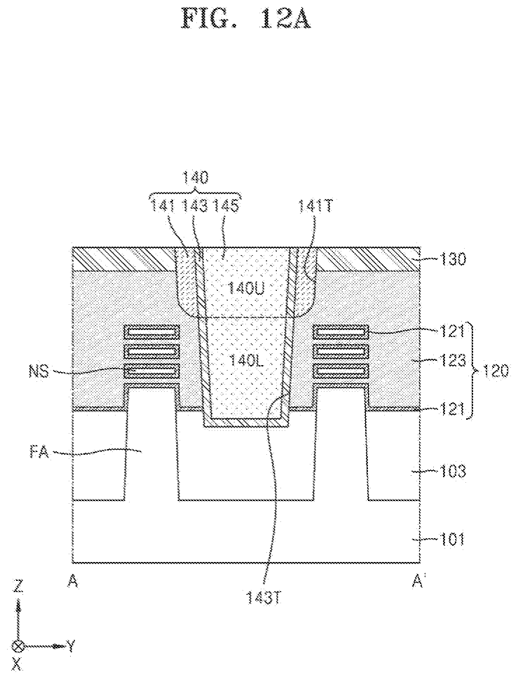

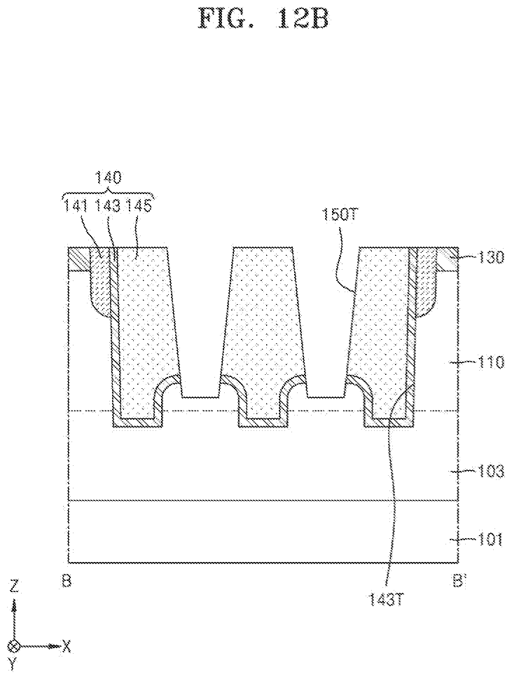

Referring to FIGS. 12A through 12C, a third trench 150T may be formed by removing the interlayer insulating layer 110 and the inter-gate cutting layer 140 by using a dry etching process so that the source/drain regions SD are exposed.

Although not shown in the drawings, a second photomask pattern (not shown) may be formed on the upper insulating layer 130 to serve as an etch mask for forming the third trench 150T. The third trench 150T may extend downward in the Z direction to expose a portion of the source/drain regions SD. According to the characteristics of the dry etching process, the third trench 150T may have a tapered shape in which its width decreases downwards. However, embodiments are not limited thereto.

Next, the second photomask pattern may be removed. The second photomask pattern may be removed through an ashing and stripping process.

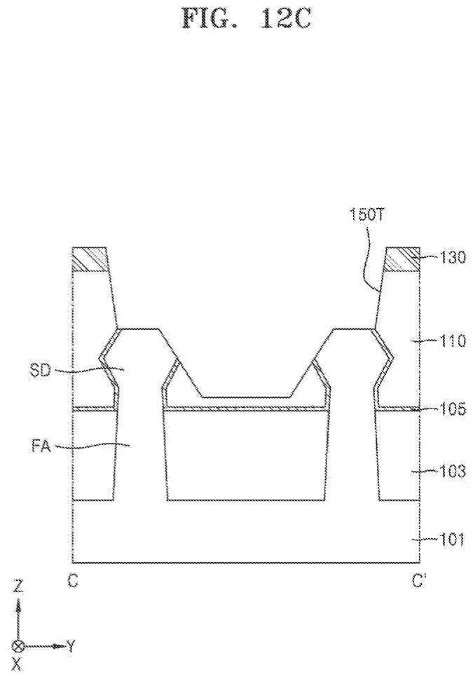

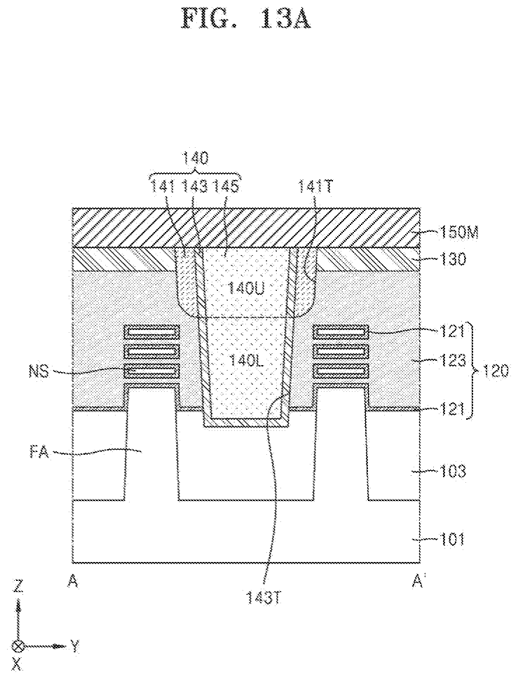

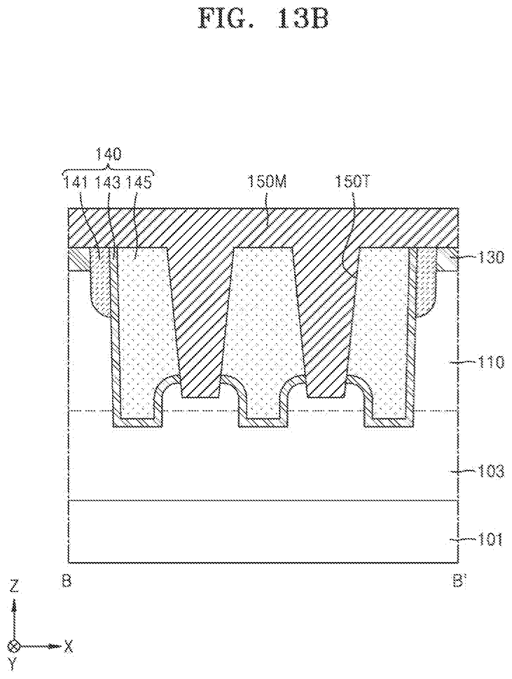

Referring to FIGS. 13A through 13C, a contact material layer 150M may be formed to cover the upper surface of the upper insulating layer 130 while filling the entire third trench 150T.

The contact material layer 150M may be formed to directly contact the source/drain regions SD. The contact material layer 150iM may pass through the interlayer insulating layer 110 and the isolation insulating layer 105 in the vertical direction (Z direction) and contact the source/drain regions SD. The contact material layer 150M may include a conductive barrier layer and a metal plug. The conductive barrier layer may be formed of Ti, Ta, TiN, TaN, or a combination thereof, but the inventive concept is not limited thereto. The metal plug may be formed of W, Co, Cu, Ru, Mn, or a combination thereof, but the inventive concept is not limited thereto.

Referring back to FIGS. 3A through 3C, a polishing process may be performed on the upper surface of the contact material layer 150M to separate the contact material layer 150M into contact structures 150. The polishing process may be performed, for example, by a chemical mechanical polishing (CMP) process or an etch-back process.

The integrated circuit device 10 according to the inventive concept manufactured by a manufacturing process as described above may provide stable performance and improved reliability in a nanosheet field effect transistor by forming the inter-gate cutting layer CT in a stepped structure and making respective horizontal widths of the inter-gate cutting layer upper portion 140U and the inter-gate cutting layer lower portion 140L different from each other.

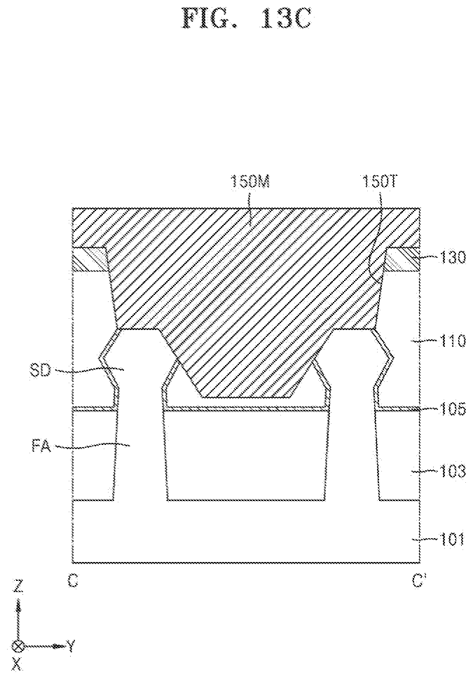

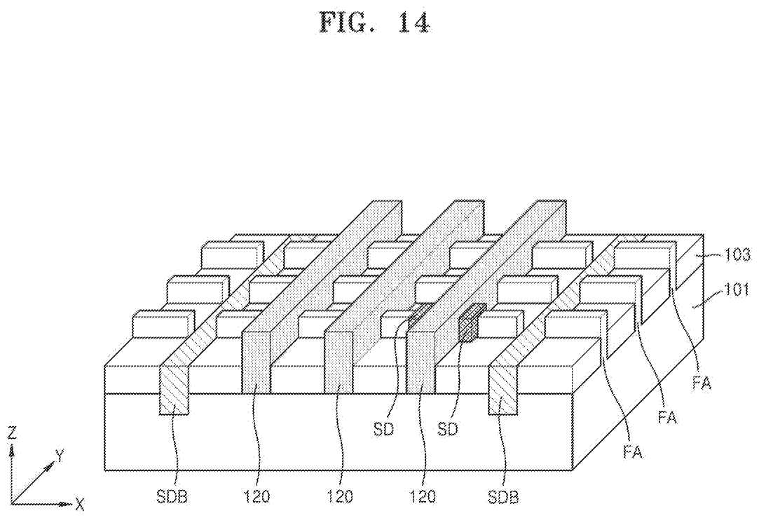

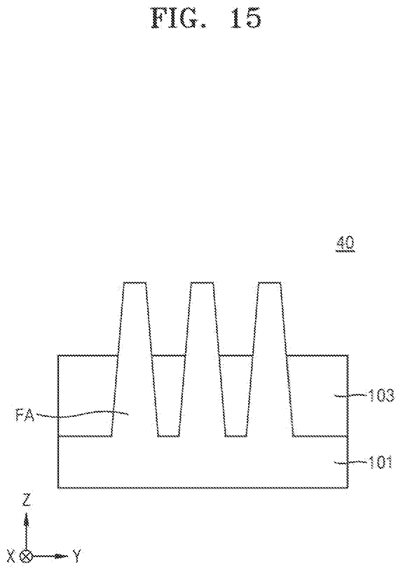

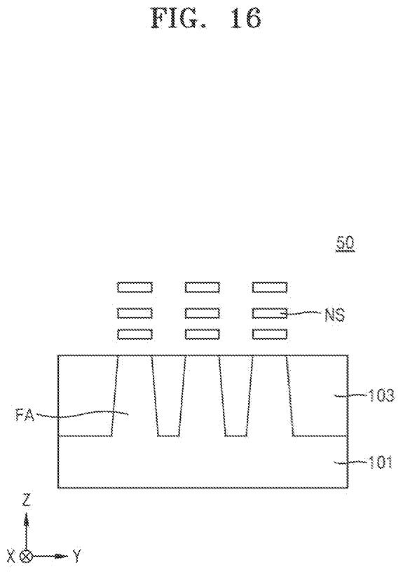

FIG. 14 is a schematic perspective view of an integrated circuit device according to an embodiment, and FIGS. 15 and 16 are cross-sectional views corresponding to active patterns of the integrated circuit device of FIG. 14.

Referring to FIGS. 14 through 16, one or more fin-type active areas FA may each extend in the first horizontal direction (X direction) on the substrate 101, and the fin-type active areas FA may form transistors by intersecting the plurality of gate structures 120 each extending in the second horizontal direction (Y direction).

The plurality of gate structures 120 may be spaced apart from each other in the first horizontal direction (X direction) on the substrate 101 and each may extend in the second horizontal direction (Y direction). The plurality of gate structures 120 may be disposed on the fin-type active areas FA and the isolation layer 103 on the substrate 101.

Single diffusion breaks SDB may be disposed between the plurality of gate structures 120. In an integrated circuit device, a standard cell is a layout unit included in an integrated circuit. A boundary between standard cells may be determined by a cell separator. The cell separator may be inserted to reduce an influence between standard cells adjacent to each other, for example, a local layout effect (LLE). The cell separator may separate fin-type active areas FA between neighboring cells and may be filled with an insulating material. According to some embodiments, the cell separator may separate the source/drain regions SD between neighboring cells by removing at least a portion of the source/drain regions SD and/or the fin-type active areas FA. The cell separator may be referred to as a single diffusion brake SDB.

According to some embodiments, the single diffusion brakes SDB may be spaced apart from each other in the first horizontal direction (X direction) on the substrate 101, and each may extend in the second horizontal direction (Y direction). The single diffusion brakes SDB may pass through the isolation layer 103 and extend into the substrate 101 to cut the source/drain regions SD and/or the fin-type active areas FA. For example, the single diffusion brakes SDB may be formed to divide the source/drain regions SD and/or the fin-type active areas FA to be isolated from each other.

As in FIG. 15, in an integrated circuit device 40, when the fin-type active areas FA each extend in the first horizontal direction (X direction), a transistor formed by a fin-type active area FA and a gate electrode 123 may be referred to as a fin-type field-effect transistor (FinFET).

As shown in FIG. 16, in an integrated circuit device 50, the fin-type active areas FA may include a plurality of nanosheet stacks NS that are spaced apart from each other in the vertical direction (Z direction) and each extend in the first horizontal direction (X direction), and a transistor formed by the plurality of nanosheet stacks NS and the gate electrode 123 may include a multi-bridge channel FET (MBCFET).

Although not shown in the drawings, an integrated circuit device may include a ForkFET having a structure in which a nanosheet for a p-type transistor and a nanosheet for an n-type transistor are separated from each other by a dielectric wall and thus n-type and p-type transistors are closer to each other.

The integrated circuit device may include a vertical FET (VFET) having a structure in which source/drain regions are spaced apart from each other in the vertical direction (Z direction) with a channel region interposed therebetween and a gate electrode surrounds the channel region.

The integrated circuit device may include a complementary FET (CFET), a negative FET (NCFET), a carbon nanotube (CNT) FET, etc., and the integrated circuit device may include a bipolar junction transistor and other three-dimensional (3D) transistors.

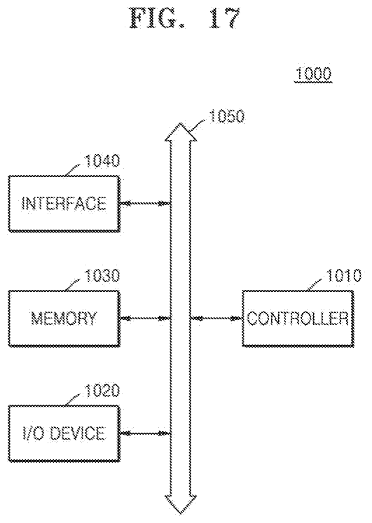

FIG. 17 is a schematic diagram of a structure of a system 1000 including an integrated circuit device according to an embodiment.

Referring to FIG. 17, the system 1000 includes a controller 1010, an input/output (I/O) device 1020, a memory 1030, an interface 1040, and a bus 1050.

The system 1000 may be an electronic device, for example, a mobile system, or a system that transmits or receives information. According to some embodiments, the mobile system may be a portable computer, a web tablet, a mobile phone, a digital music player, or a memory card.

The controller 1010 controls programs that are executed in the system 1000, and may be a microprocessor, a digital signal processor, a microcontroller, or a device similar to these devices.

The I/O device 1020 may be used to input or output the data of the system 1000. The system 1000 may be connected to an external device, for example, a personal computer or a network, by using the I/O device 1020, and may exchange data with the external device. The I/O device 1020 may be, for example, a touch screen, a touch pad, a keyboard, or a display.

The memory 1030 may store data for operating the controller 1010, or store data processed by the controller 1010. The memory 1030 may include any one or more of the integrated circuit devices 10, 20, 30, 40, and 50 according to the inventive concept described above.

The interface 1040 may be a data transmission path between the system 1000 and another external device. The controller 1010, the I/O device 1020, the memory 1030, and the interface 1040 may communicate with each other via the bus 1050.

While the inventive concept has been particularly shown and described with reference to embodiments thereof, it will be understood that various changes in form and details may be made therein without departing from the spirit and scope of the invention.

1. An integrated circuit device comprising:
a plurality of fin-type active areas each extending on a substrate in a first horizontal direction;
a plurality of gate structures each extending in a second horizontal direction intersecting the plurality of fin-type active areas on the substrate, the plurality of gate structures being spaced apart from each other in the first horizontal direction;
an interlayer insulating layer covering a periphery of the plurality of gate structures; and
an inter-gate cutting layer formed of an insulating material and extending in the first horizontal direction through the plurality of gate structures and the interlayer insulating layer,
wherein
a first gate structure of the plurality of gate structures is separated from a second gate structure of the plurality of gate structures by the inter-gate cutting layer, and
portions of respective side surfaces of the plurality of gate structures overlap the plurality of fin-type active areas in a vertical direction, the respective side surfaces of the plurality of gate structures extending in the first horizontal direction.

2. The integrated circuit device of claim 1, wherein the inter-gate cutting layer has a step such that a width of an upper portion of the inter-gate cutting layer in the second horizontal direction is different from a width of a lower portion of the inter-gate cutting layer in the second horizontal direction.

3. The integrated circuit device of claim 2, wherein, based on the step, the upper portion of the inter-gate cutting layer includes a first insulating liner at an outermost portion in the second horizontal direction, and based on the step, the lower portion of the inter-gate cutting layer does not include the first insulating liner at an outermost portion in the second horizontal direction.

4. The integrated circuit device of claim 3, wherein the inter-gate cutting layer comprises:
a second insulating liner extending through the upper portion of the inter-gate cutting layer and along outer surfaces of the lower portion of the inter-gate cutting layer and along a lower surface of the inter-gate cutting layer; and
an insulating pattern filling a space defined by the second insulating liner,
wherein a natural oxide layer is disposed between the first insulating liner and the second insulating liner.

5. The integrated circuit device of claim 4, wherein the first insulating liner and the second insulating liner are formed of substantially the same materials.

6. The integrated circuit device of claim 5, wherein
each of the first insulating liner and the second insulating liner is formed of silicon nitride, and
the insulating pattern is formed of silicon oxide.

7. The integrated circuit device of claim 4, wherein the first insulating liner and the second insulating liner are formed of different materials from each other.

8. The integrated circuit device of claim 7, wherein
the first insulating liner is formed of silicon nitride,
the second insulating liner is formed of silicon oxynitride, and
the insulating pattern is formed of silicon oxide.

9. The integrated circuit device of claim 3, wherein, an outer wall of the upper portion of the inter-gate cutting layer, which extends in the second horizontal direction, overlaps the fin-type active areas in the vertical direction, and
an outer wall of the lower portion of the inter-gate cutting layer is spaced apart from the fin-type active areas in the second horizontal direction.

10. The integrated circuit device of claim 1, further comprising a plurality of nanosheet stacks respectively disposed over the plurality of fin-type active areas, each of the plurality of nanosheet stacks comprising at least one nanosheet surrounded by a respective gate structure of the plurality of gate structures,
wherein the portions of the respective side surfaces of the plurality of gate structures overlap the plurality of nanosheet stacks in the vertical direction.

11. An integrated circuit device comprising:
first and second fin-type active areas each extending in a first horizontal direction on a substrate and spaced apart from each other in a second horizontal direction crossing the first horizontal direction;
a gate structure extending in the second horizontal direction to intersect the first and second fin-type active areas on the substrate;
an inter-gate isolation trench cutting through the gate structure in the first horizontal direction; and
an inter-gate cutting layer filling the inter-gate isolation trench and having an upper portion and a lower portion, wherein a sidewall of the upper portion includes a first insulating liner and a second insulating liner, and a sidewall of the lower portion includes the second insulating liner,
wherein the first insulating liner overlaps the first and second fin-type active areas in a vertical direction, and the second insulating liner does not overlap the first and second fin-type active areas in the vertical direction.

12. The integrated circuit device of claim 11, wherein a maximum width of the upper portion of the inter-gate cutting layer in the second horizontal direction is greater than a separation distance between the first and second fin-type active areas.

13. The integrated circuit device of claim 12, wherein, in the second horizontal direction, a separation distance between respective side surfaces of the lower portion of the inter-gate cutting layer and respective side surfaces of the first and second fin-type active areas is greater than a width of the first insulating liner in the second horizontal direction.

14. The integrated circuit device of claim 11, wherein a natural oxide layer is disposed between the first insulating liner and the second insulating liner, in the upper portion of the inter-gate cutting layer.

15. The integrated circuit device of claim 11, further comprising first and second nanosheet stacks respectively disposed over the first and second fin-type active areas, each of the first and second nanosheet stacks comprising at least one nanosheet surrounded by the gate structure,
wherein the first insulating liner overlaps the first and second nanosheet stacks in the vertical direction, and the second insulating liner does not overlap the first and second nanosheet stacks in the vertical direction.

16. An integrated circuit device comprising:
a plurality of fin-type active areas each extending on a substrate in a first horizontal direction;
a plurality of nanosheet stacks respectively disposed over the plurality of fin-type active areas and each comprising at least one nanosheet;
a plurality of gate structures each extending in a second horizontal direction intersecting the plurality of fin-type active areas on the substrate, spaced apart from each other in the first horizontal direction, and surrounding the plurality of nanosheet stacks;
an interlayer insulating layer covering a periphery of the plurality of gate structures;
an inter-gate isolation trench cutting through the plurality of gate structures in the first horizontal direction; and
an inter-gate cutting layer filling the inter-gate isolation trench and having an upper portion and a lower portion, wherein a sidewall of the upper portion includes a first insulating liner and a second insulating liner, and a sidewall of the lower portion includes the second insulating liner,
wherein the first insulating liner overlaps the plurality of nanosheet stacks in a vertical direction, and the second insulating liner does not overlap the plurality of nanosheet stacks in the vertical direction.

17. The integrated circuit device of claim 16, wherein
the first insulating liner and the second insulating liner are formed of substantially the same materials, and
a natural oxide layer is disposed between the first insulating liner and the second insulating liner.

18. The integrated circuit device of claim 16, wherein the first insulating liner and the second insulating liner are formed of different materials from each other.

19. The integrated circuit device of claim 16, wherein a maximum width of the upper portion of the inter-gate cutting layer in the second horizontal direction is greater than a separation distance between the plurality of nanosheet stacks.

20. The integrated circuit device of claim 16, wherein, in the second horizontal direction, a separation distance between respective side surfaces of the lower portion of the inter-gate cutting layer and respective side surfaces of the plurality of nanosheet stacks is greater than a width of the first insulating liner.

21. (canceled)
